(19) United States
(12) Patent Application Publication
(10) Pub. No.: US 2017/0162411 A1
(43) Pub. Date: Jun. 8, 2017

(54) TRAY

(71) Applicant: NANYA TECHNOLOGY CORPORATION, Taoyuan City (TW)

(72) Inventor: Han-Ning PEI, Taipei City (TW)

(21) Appl. No.: 14/958,900

(22) Filed: Dec. 3, 2015

(51) Int. Cl. H01L 21/673

(52) U.S. Cl. CPC H01L 21/67333

(57) ABSTRACT

A tray for holding an integrated circuit component includes a base frame and at least a pair of supporting walls. The supporting walls are connected to the base frame. The supporting walls are opposite to each other. Each of the supporting walls has a curved surface substantially facing to each other. The curved surfaces are configured to respectively support at least two portions of the integrated circuit component. A gap exists between the integrated circuit component and the base frame when the integrated circuit component is held by the curved surfaces.

### BACKGROUND

Technical Field

The present disclosure relates to trays. More particularly, the present disclosure relates to trays for holding integrated circuit components.

Description of Related Art

During the manufacturing procedure of integrated circuit components, the integrated circuit components have to be transported between various machines or equipment for processing or testing. Afterwards, when the integrated circuit components become the finished goods, they have to be then transported for the consequent assembly procedure.

In order to improve the efficiency of transportation of the integrated circuit components between different spots, trays are generally and systematically utilized to hold and support the integrated circuit components.

### SUMMARY

A technical aspect of the present disclosure provides a tray, which can avoid the damage of an integrated circuit component to be held due to compression or friction during transportation.

According to an embodiment of the present disclosure, a tray for holding an integrated circuit component includes a base frame and at least a pair of supporting walls. The supporting walls are connected to the base frame. The supporting walls are opposite to each other. Each of the supporting walls has a curved surface substantially facing to each other. The curved surfaces are configured to respectively support at least two portions of the integrated circuit component. A gap exists between the integrated circuit component and the base frame when the integrated circuit component is held by the curved surfaces.

In one or more embodiments of the present disclosure, the curved surfaces face substantially away from the base frame.

In one or more embodiments of the present disclosure, the curved surfaces are concave in shape.

In one or more embodiments of the present disclosure, the curved surfaces are convex in shape.

In one or more embodiments of the present disclosure, a plurality of distances exists between the supporting walls in an arrangement direction of the supporting walls. The distances diminish towards the base frame.

In one or more embodiments of the present disclosure, the distances diminish increasingly towards the base frame.

In one or more embodiments of the present disclosure, the distances diminish decreasingly towards the base frame.

In one or more embodiments of the present disclosure, the tray further includes two pairs of the supporting walls. An arrangement direction of one pair of the supporting walls is substantially perpendicular to an arrangement direction of the other pair of the supporting walls.

In one or more embodiments of the present disclosure, a distance between the supporting walls in the arrangement direction of one pair is larger than a width of the supporting walls of the other pair in a direction substantially perpendicular to the arrangement direction of the other pair.

When compared with the prior art, the above-mentioned embodiments of the present disclosure have at least the following advantages:

(1) When the integrated circuit component is held by the curved surfaces of the supporting walls, the gap exists between the integrated circuit component and the base frame. In other words, the integrated circuit component does not contact with the base frame. In this way, the chance that the integrated circuit component is damaged due to compression to the base frame or friction against the base frame during transportation is avoided.

(2) Since the integrated circuit component is held by the curved surfaces of the supporting walls, the area of contact of the supporting walls supporting the integrated circuit component is reduced. In this way, when the integrated circuit component is put in the tray or taken away from the tray, the chance that the integrated circuit component is rubbed against the curved surfaces is also reduced. Thus, the procedure to put the integrated circuit component in the tray or take the integrated circuit component away from the tray becomes easier and simpler.

(3) Since the curved surfaces substantially face to each other and the distances between the supporting walls diminish towards the base frame, when the integrated circuit component is put in the tray, the curved surfaces assist to guide the integrated circuit component into the tray. Thus, it is convenient to put the integrated circuit component into the tray.

### BRIEF DESCRIPTION OF THE DRAWINGS

The disclosure can be more fully understood by reading the following detailed description of the embodiments, with reference made to the accompanying drawings as follows:

FIG. 1 is a schematic diagram of a tray according to an embodiment of the present disclosure, in which an integrated circuit component is held;

FIG. 2 is a sectional view along the section line X-X of FIG. 1; and

FIG. 3 is a sectional view of a tray according to another embodiment of the present disclosure, in which an integrated circuit component is held.

### DETAILED DESCRIPTION

Drawings will be used below to disclose a plurality of embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

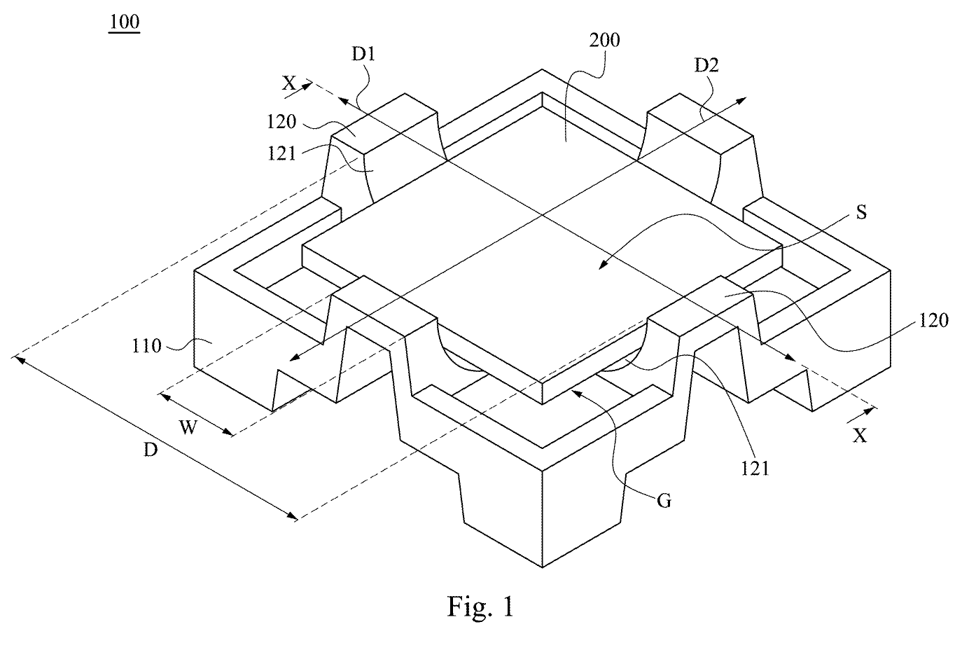

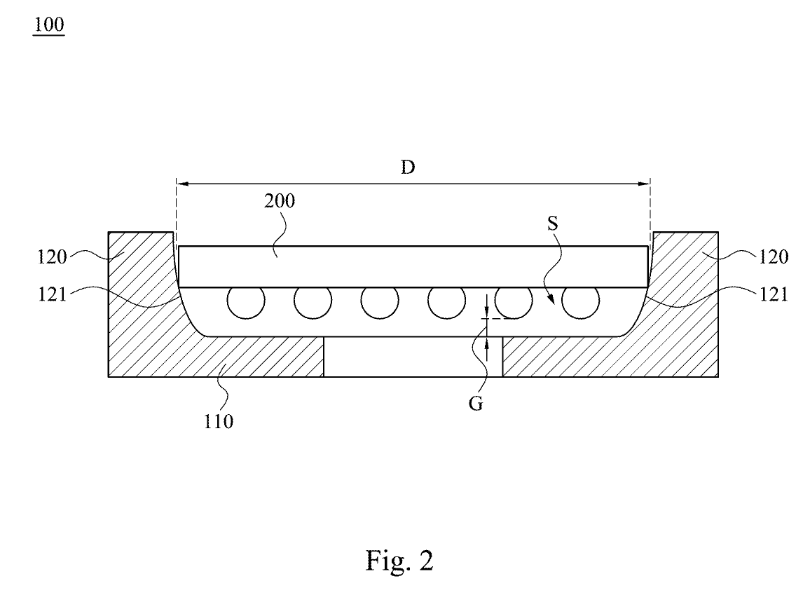

Reference is made to FIGS. 1 and 2. FIG. 1 is a schematic diagram of a tray 100 according to an embodiment of the present disclosure, in which an integrated circuit component 200 is held. FIG. 2 is a sectional view along the section line X-X of FIG. 1. As shown in FIGS. 1 and 2, a tray 100 for holding an integrated circuit component 200 is provided. The tray 100 includes a base frame 110 and at least a pair of supporting walls 120. The supporting walls 120 are connected to the base frame 110. The supporting walls 120 are opposite to each other. Each of the supporting walls 120 has a curved surface 121 substantially facing to each other. The curved surfaces 121 are configured to respectively support at least two portions of the integrated circuit component 200. A gap G exists between the integrated circuit component 200 and the base frame 110 when the integrated circuit component 200 is held by the curved surfaces 121.

In practical applications, when the integrated circuit component 200 is transported between machines in a production line, or as a finished product to be packaged, the tray 100 is utilized to hold and support the integrated circuit component 200. As mentioned above, when the integrated circuit component 200 is held by the curved surfaces 121 of the supporting walls 120, the gap G exists between the integrated circuit component 200 and the base frame 110. In other words, the integrated circuit component 200 does not contact with the base frame 110. In this way, the chance that the integrated circuit component 200 is damaged due to compression to the base frame 110 or friction against the base frame 110 during transportation is avoided.

To be more specific, in order to facilitate the integrated circuit component 200 to be put in the tray 100 or taken away from the tray 100, the curved surfaces 121 face substantially away from the base frame 110.

Furthermore, since the integrated circuit component 200 is held by the curved surfaces 121 of the supporting walls 120, the area of contact of the supporting walls 120 supporting the integrated circuit component 200 is reduced. In this way, when the integrated circuit component 200 is put in the tray 100 or taken away from the tray 100, the chance that the integrated circuit component 200 is rubbed against the curved surfaces 121 is also reduced. Thus, the procedure to put the integrated circuit component 200 in the tray 100 or take the integrated circuit component 200 away from the tray 100 becomes easier and simpler. In this embodiment, as shown in FIG. 2, the curved surfaces 121 of the supporting walls 120 are concave in shape.

In addition, as shown in FIGS. 1-2, a plurality of distances D exists between the curved surfaces 121 of the supporting walls 120 in an arrangement direction D1 of the supporting walls 120, and the distances D diminish towards the base frame 110. In this way, when the integrated circuit component 200 is put in the tray 100, the curved surfaces 121 assist to guide the integrated circuit component 200 between the supporting walls 120. Thus, it is convenient to put the integrated circuit component 200 into the tray 100. Furthermore, as mentioned above, the curved surfaces 121 of the supporting walls 120 are concave in shape. This means that the distances D diminish increasingly towards the base frame 110.

In other words, the supporting walls 120 form a space S in between and the space S is configured to accommodate the integrated circuit component 200. Since the curved surfaces 121 substantially face to each other as mentioned above and the space S diminishes towards the base frame 110, when the integrated circuit component 200 is put in the tray 100, the curved surfaces 121 assist to guide the integrated circuit component 200 into the space S. Thus, it is convenient to put the integrated circuit component 200 into the space S.

Furthermore, in practical applications, any dust arriving the curved surfaces 121 will be easily slid along the curved surfaces 121 and the chance that the dust is accumulated on the curved surfaces 121 is reduced. Thus, the contamination by dust to the curved surfaces 121 of the supporting walls 120 is prevented. Moreover, the tray 100, especially the curved surfaces 121, is convenient and easy to be cleaned.

In order to hold and support the integrated circuit component 200 in a stable manner, as shown in FIG. 1, the tray 100 further includes two pairs of the supporting walls 120. Meanwhile, the arrangement direction D1 of one pair of the supporting walls 120 is substantially perpendicular to the arrangement direction D2 of the other pair of the supporting walls 120. In this way, the integrated circuit component 200 can be held and supported by the four supporting walls 120 of the tray 100 in a stable manner.

Structurally speaking, as shown in FIG. 1, the distance D between the supporting walls 120 in the arrangement direction D1 of one pair is larger than a width W of the supporting walls 120 of the other pair in a direction substantially perpendicular to the arrangement direction D2 of the other pair. In this way, the corners of the integrated circuit component 200 will not be supported by the curved surfaces 121 of the supporting walls 120. This means, the corners of the integrated circuit component 200 are free from the supporting walls 120. In this way, the procedure to put the integrated circuit component 200 in the tray 100 or take the integrated circuit component 200 away from the tray 100 becomes easier and simpler.

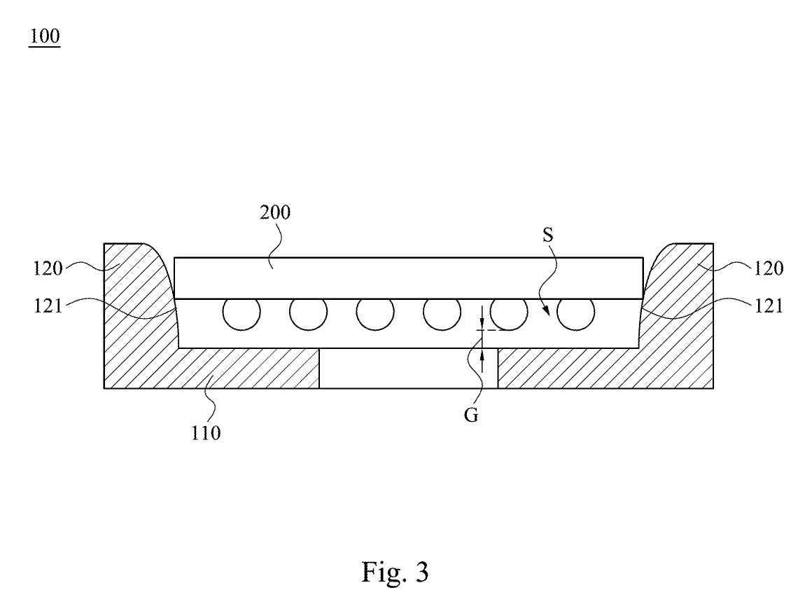

Reference is made to FIG. 3. FIG. 3 is a sectional view of a tray 100 according to another embodiment of the present disclosure, in which an integrated circuit component 200 is held. According to actual situations, as shown in FIG. 3, the curved surfaces 121 of the supporting walls 120 can be convex in shape. In other words, the distances D between the supporting walls 120 diminish decreasingly towards the base frame 110.

In summary, when compared with the prior art, the embodiments of the present disclosure mentioned above have at least the following advantages:

(1) When the integrated circuit component is held by the curved surfaces of the supporting walls, the gap exists between the integrated circuit component and the base frame. In other words, the integrated circuit component does not contact with the base frame. In this way, the chance that the integrated circuit component is damaged due to compression to the base frame or friction against the base frame during transportation is avoided.

(2) Since the integrated circuit component is held by the curved surfaces of the supporting walls, the area of contact of the supporting walls supporting the integrated circuit component is reduced. In this way, when the integrated circuit component is put in the tray or taken away from the tray, the chance that the integrated circuit component is rubbed against the curved surfaces is also reduced. Thus, the procedure to put the integrated circuit component in the tray or take the integrated circuit component away from the tray becomes easier and simpler.

(3) Since the curved surfaces substantially face to each other and the distances between the supporting walls diminish towards the base frame, when the integrated circuit component is put in the tray, the curved surfaces assist to guide the integrated circuit component into the tray. Thus, it is convenient to put the integrated circuit component into the tray.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

1. A tray for holding an integrated circuit component, comprising:
a base frame; and
two pairs of supporting walls connected to the base frame, the supporting walls of each of the two pairs being opposite to each other, each of the supporting walls of each of the two pairs having a curved surface, the curved surfaces of each of the two pairs of the supporting walls substantially facing to each other, the curved surfaces of each of the two pairs of the supporting walls being configured to respectively support at least two portions of the integrated circuit component, wherein an arrangement direction of one pair of the supporting walls is substantially perpendicular to an arrangement direction of the other pair of the supporting walls, a distance between the supporting walls in the arrangement direction of one pair is larger than a width of the supporting walls of the other pair in a direction substantially perpendicular to the arrangement direction of the other pair, any adjacent two of the curved surfaces form an opening therebetween, the base frame has an upper surface, the upper surface has a central part and a plurality of extending parts, the central part connects among the curved surfaces and each of the extending parts connects to the central part and extends outwards from the corresponding opening, and a gap exists between the integrated circuit component and the base frame when the integrated circuit component is held by the curved surfaces.

2. The tray of claim 1, wherein the curved surfaces of the supporting walls substantially face away from the base frame.

3. The tray of claim 1, wherein the curved surfaces are concave in shape.

4. The tray of claim 1, wherein the curved surfaces are convex in shape.

5. The tray of claim 1, wherein a plurality of distances exists between the supporting walls of each of the two pairs in an arrangement direction of the pair of the supporting walls, and the distances diminish towards the base frame.

6. The tray of claim 5, wherein the distances diminish increasingly towards the base frame.

7. The tray of claim 5, wherein the distances diminish decreasingly towards the base frame.

8-9. (canceled)
